(19) United States
(12) Patent Application Publication
(10) Pub. No.: US 2025/0372557 A1
(43) Pub. Date: Dec. 4, 2025

(54) ELECTRONIC COMPONENT, HIGH-FREQUENCY MODULE, AND COMMUNICATION DEVICE

(71) Applicant: Murata Manufacturing Co., Ltd., Kyoto-fu (JP)

(72) Inventor: Masakazu HORI, Nagaokakyo-shi (JP)

(73) Assignee: Murata Manufacturing Co., Ltd., Kyoto-fu (JP)

(21) Appl. No.: 19/220,406

(22) Filed: May 28, 2025

(30) Foreign Application Priority Data
May 29, 2024 (JP) 2024-087226

(51) Int. Cl. H01L 23/00; H01L 23/66

(52) U.S. Cl. CPC H01L 24/13; H01L 23/66; H01L 24/16; H01L 2224/13014; H01L 2224/13018; H01L 2224/13552; H01L 2224/1357; H01L 2224/16059; H01L 2224/16227; H01L 2224/16238; H01L 2924/13091

(57) ABSTRACT

An electronic component includes a substrate and a pillar electrode. The substrate includes a first principal surface. The pillar electrode protrudes from the first principal surface of the substrate in a thickness direction of the substrate. The pillar electrode is positioned between the first principal surface of the substrate and a bump electrode. The pillar electrode includes a second principal surface and a peripheral surface. The second principal surface is in contact with the bump electrode. The peripheral surface is connected to the second principal surface and to the first principal surface of the substrate. The pillar electrode includes a groove disposed at the second principal surface of the pillar electrode. A bottom of the groove is connected to the peripheral surface of the pillar electrode.

### CROSS-REFERENCE TO RELATED APPLICATION

This application claims benefit of priority to Japanese Patent Application No. 2024-087226, filed May 29, 2024, the entire content of which is incorporated herein by reference.

### BACKGROUND

### Technical Field

The present disclosure relates to an electronic component, a high-frequency module, and a communication device and more particularly relates to an electronic component including a pillar electrode, a high-frequency module equipped with the electronic component, and a communication device equipped with the high-frequency module.

### Background Art

Japanese Unexamined Patent Application Publication No. 2017-152646 discloses an electronic component that includes a pillar electrode. The electronic component of Japanese Unexamined Patent Application Publication No. 2017-152646 includes the pillar electrode as a terminal. The pillar electrode has a principal surface at which a recess is formed, and a solder portion (bump electrode) is disposed on the principal surface.

### SUMMARY

In the electronic component of Japanese Unexamined Patent Application Publication No. 2017-152646, however, if gas is produced from a soldering flux or the like when the solder portion melts, bubbles may stay in the recess at the principal surface of the pillar electrode and generate a void between the pillar electrode and an electrode to which the pillar electrode is connected. When the electronic component is mounted on a circuit board, the void, in which no solder is present, may cause poor electrical connection and poor heat transfer between the electronic component and the circuit board, which may lead to malfunction of the electronic component.

Accordingly, the present disclosure provides an electronic component, a high-frequency module, and a communication device, in which the reliability of connection is improved between the pillar electrode and the electrode of the circuit board.

According to an aspect of the present disclosure, an electronic component includes a substrate and a pillar electrode. The substrate includes a first principal surface. The pillar electrode protrudes from the first principal surface of the substrate in a thickness direction of the substrate. The pillar electrode is positioned between the first principal surface of the substrate and a bump electrode. The pillar electrode includes a second principal surface and a peripheral surface. The second principal surface is in contact with the bump electrode. The peripheral surface is connected to the second principal surface. The pillar electrode includes a groove disposed at the second principal surface of the pillar electrode. A bottom of the groove is connected to the peripheral surface of the pillar electrode.

According to another aspect of the present disclosure, a high-frequency module includes the electronic component and a circuit board. The electronic component is disposed on the circuit board.

According to another aspect of the present disclosure, a communication device includes the high-frequency module and a signal processing circuit. The signal processing circuit is connected to the high-frequency module.

In the electronic component, the high-frequency module, and the communication device according to an aspect of the present disclosure, the reliability of connection between the pillar electrode and the electrode of the circuit board can be improved.

### BRIEF DESCRIPTION OF THE DRAWINGS

FIG. 1 is a plan view illustrating part of a high-frequency module according to Embodiment 1;

FIG. 2 is a cross-sectional view illustrating part of the high-frequency module of Embodiment 1, the view being taken along section X1-X1 in FIG. 1;

FIG. 3A is a cross-sectional view illustrating a relevant part of an electronic component according to Embodiment 1;

FIG. 3B is a plan view illustrating the relevant part of the electronic component of Embodiment 1;

FIG. 4 is a cross-sectional view illustrating the relevant part of the electronic component of Embodiment 1;

FIG. 5 is a view illustrating a circuit structure of a communication device equipped with the high-frequency module of Embodiment 1;

FIG. 6 is a circuit diagram of a power amplifier included in the electronic component of Embodiment 1;

FIG. 7A is a cross-sectional view illustrating a relevant part of an electronic component according to Embodiment 2;

FIG. 7B is a plan view illustrating the relevant part of the electronic component of Embodiment 2;

FIG. 8A is a cross-sectional view illustrating a relevant part of an electronic component according to Embodiment 3;

FIG. 8B is a plan view illustrating the relevant part of the electronic component of Embodiment 3;

FIG. 9A is a cross-sectional view illustrating a relevant part of an electronic component according to Embodiment 4;

FIG. 9B is a plan view illustrating the relevant part of the electronic component of Embodiment 4;

FIG. 10 is another cross-sectional view illustrating the relevant part of the electronic component of Embodiment 4;

FIG. 11A is a cross-sectional view illustrating a relevant part of an electronic component according to Embodiment 5;

FIG. 11B is a plan view illustrating the relevant part of the electronic component of Embodiment 5;

FIG. 12A is a cross-sectional view illustrating a relevant part of an electronic component according to Embodiment 6; and

FIG. 12B is a plan view illustrating the relevant part of the electronic component of Embodiment 6.

### DETAILED DESCRIPTION

An electronic component, a high-frequency module, and a communication device of each embodiment will be described with reference to the drawings. The drawings to be referred to for describing the embodiments are schematic illustrations, and dimensional ratios in size and thickness of elements illustrated in the drawings do not necessarily reflect actual ratios.

### Embodiment 1

### 1 Electronic Component

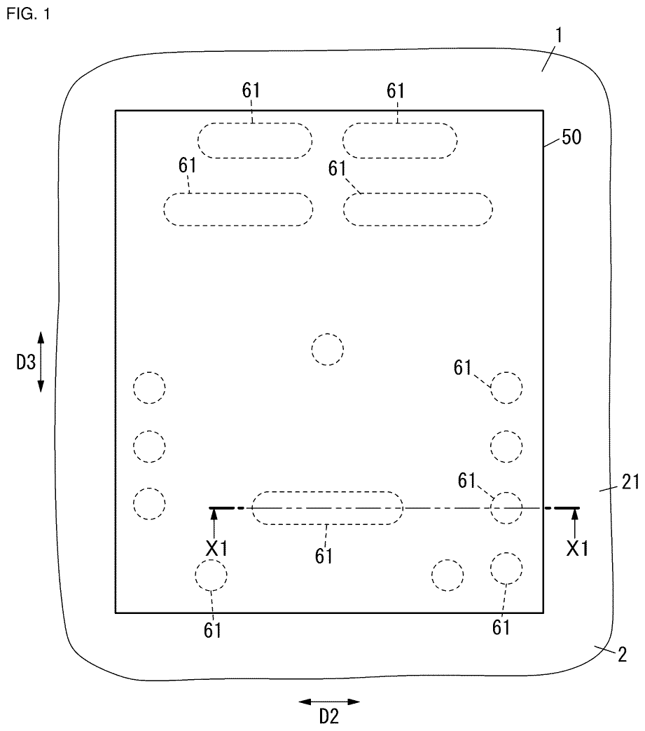

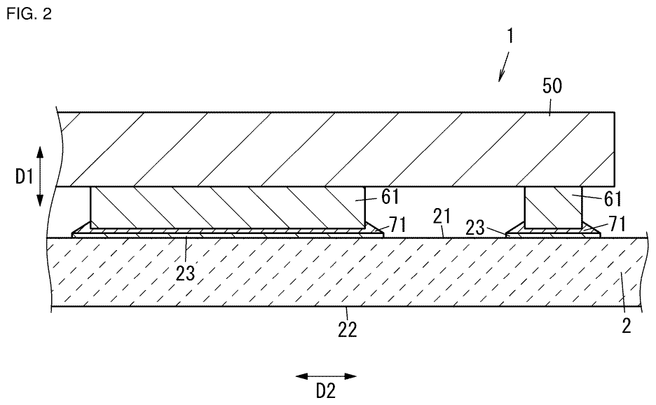

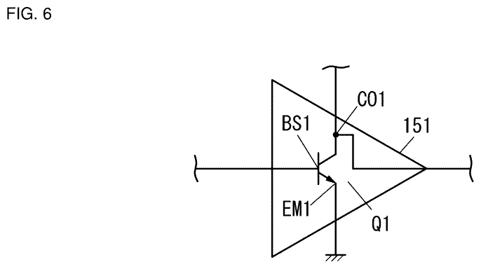

As illustrated in FIGS. 1 and 2, an electronic component 50 is disposed on a circuit board 2. For example, the electronic component 50 is an IC chip that includes a transistor. More specifically, the electronic component 50 includes at least one of a switch 110 (see FIG. 5), a low-noise amplifier 152 (see FIG. 5), and a power amplifier 151 (see FIG. 5). Even more specifically, in the case of the electronic component 50 including the power amplifier 151, the electronic component 50 includes a transistor Q1 (see FIG. 6) contained in the power amplifier 151. In the case of the electronic component 50 including the low-noise amplifier 152, the electronic component 50 includes a transistor (not illustrated) contained in the low-noise amplifier 152. In the case of the electronic component 50 including the switch 110, the electronic component 50 includes a transistor (not illustrated) contained in the switch 110. In addition, for example, the electronic component 50 may include an acoustic wave oscillator contained in a transmission filter 131 or may include an acoustic wave oscillator contained in a reception filter 132. For example, the acoustic wave oscillator includes either a surface acoustic wave (SAW) oscillator or a bulk acoustic wave (BAW) oscillator.

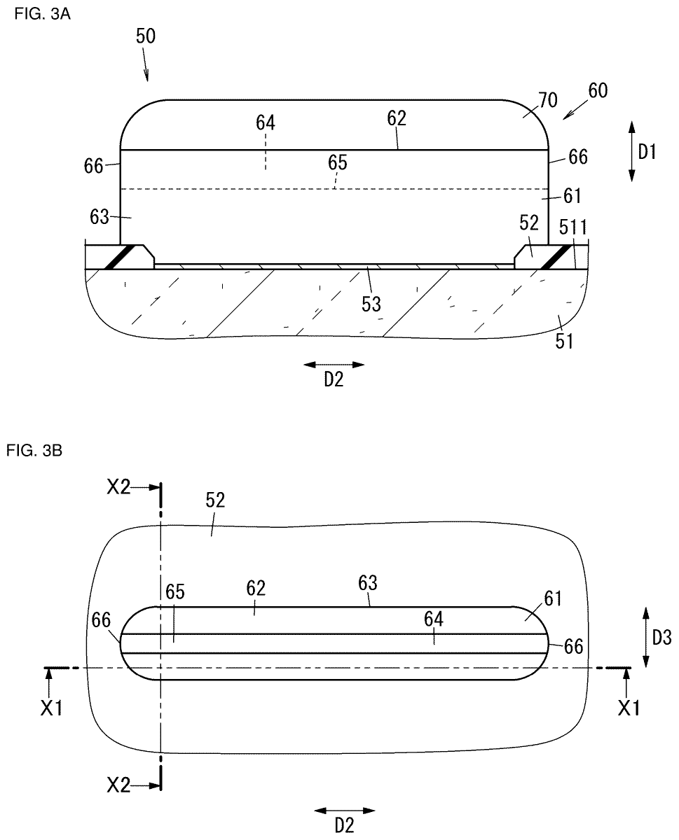

As indicated in FIG. 3A, the electronic component 50 includes a substrate 51 and multiple connection electrodes 60 although FIG. 3A illustrates only one of them. The connection electrodes 60 are disposed on a principal surface 511 of the substrate 51. The principal surface 511 corresponds to the first principal surface of the present disclosure. Each of the connection electrodes 60 includes a pillar electrode 61 and a bump electrode 70. The pillar electrode 61 is positioned between the bump electrode 70 and the principal surface 511 of the substrate 51.

### 1.1 Connection Electrode

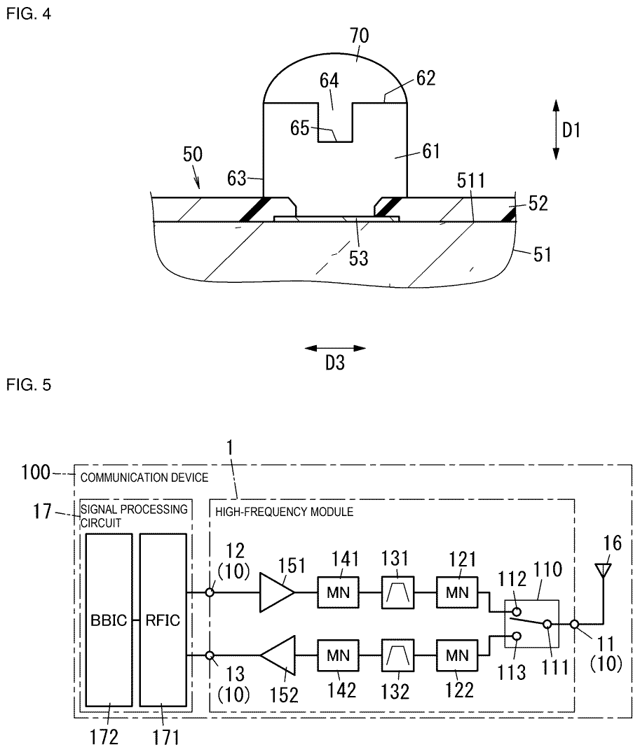

As illustrated in FIGS. 3A, 3B, and 4, each connection electrode 60 is disposed on the principal surface 511 of the substrate 51. FIG. 3A is a cross-sectional view corresponding to section X1-X1 in FIG. 3B. FIG. 4 is a cross-sectional view corresponding to section X2-X2 in FIG. 3B. Note that in FIGS. 3A and 4, the hatching for indicating the cross-section is omitted from the illustration of the pillar electrode 61 and the bump electrode 70 of the connection electrode 60. The principal surface 511 opposes the circuit board 2 when the electronic component 50 is disposed on the circuit board 2 (see FIGS. 1 and 2). More specifically, the electronic component 50 has multiple electrodes 53 formed on the principal surface 511 of the substrate 51 (note that only one electrode 53 is shown in FIGS. 3A and 4), each connection electrode 60 is connected to a corresponding one of the multiple electrodes 53. Note that an insulating layer 52 is disposed on the principal surface 511 of the substrate 51 where the connection electrodes 60 are not disposed.

Each connection electrode 60 is a column-shaped electrode extending in a thickness direction D1 of the substrate 51.

The connection electrode 60 includes the pillar electrode 61 and the bump electrode 70. Note that the bump electrode 70 is omitted in FIG. 3B.

The pillar electrode 61 extends in the thickness direction D1 of the substrate 51. For example, the pillar electrode 61 is elongated in a direction orthogonal to the direction D1. More specifically, the pillar electrode 61 is elongated, for example, in the direction D2 that orthogonally intersects the direction D1. With this configuration, the heat of the electronic component 50 can be diffused efficiently to the circuit board 2 via the pillar electrode 61. Moreover, the electric resistance of the pillar electrode 61 can be reduced.

Especially in the case of the pillar electrode 61 being connected to one of the electrodes of the transistor Q1 (see FIG. 6) included in the electronic component 50, the heat of the transistor Q1 can be diffused to the circuit board 2 efficiently. More specifically, the pillar electrode 61 is connected to the emitter of the transistor Q1 in such a case.

The pillar electrode 61 has a principal surface 62 positioned at a first end thereof in the direction D1. The bump electrode 70 is disposed on the principal surface 62 of the pillar electrode 61. In other words, the principal surface 62 of the pillar electrode 61 is in contact with the bump electrode 70. The principal surface 62 corresponds to the second principal surface of the present disclosure. The second end of the pillar electrode 61 in the direction D1 is connected to an electrode 53. The pillar electrode 61 has a peripheral surface 63 connected to two principal surfaces 62 of the pillar electrode 61. In other words, the peripheral surface 63 of the pillar electrode 61 is connected to the principal surfaces 62 thereof.

The pillar electrode 61 is made of a conductive material of which the melting point is higher than that of the material of the bump electrode 70. More specifically, the pillar electrode 61 is made of a material that is not softened at a temperature at which the material of the bump electrode 70 melts, in other words, at an inside temperature of the reflow furnace. For example, the material of the pillar electrode 61 is copper or gold or an alloy of these.

The bump electrode 70 is disposed on a principal surface 62 of the pillar electrode 61 before the electronic component 50 is mounted onto the circuit board 2. For example, the material of the bump electrode 70 is solder. When the electronic component 50 is disposed on the circuit board 2, the bump electrode 70 melts to connect the electronic component 50 to the circuit board 2. More specifically, when the electronic component 50 is mounted onto the circuit board 2, the bump electrode 70 melts and is shaped into a solder portion 71 that connects each pillar electrode 61 electrically and mechanically to the corresponding one of the electrodes 23 disposed on a principal surface 21 of the circuit board 2 as illustrated in FIG. 2.

### 1.2 Pillar Electrode

As illustrated in FIGS. 3A, 3B, and 4, the pillar electrode 61 has a groove 64 recessed in the direction D1. The groove 64 of the pillar electrode 61 is formed at the principal surface 62 of the pillar electrode 61. As viewed in plan in the direction D1, the groove 64 extends straight. For example, the groove 64 is elongated in the direction D2, which is the longitudinal direction of the pillar electrode 61. The groove 64 of the pillar electrode 61 has a bottom 65. For example, the bottom 65 of the groove 64 is a flat surface. This means not only a case in which the bottom 65 of the groove 64 is perfectly flat but also a case in which the bottom 65 of the groove 64 has minute irregularities.

The bottom 65 of the groove 64 of the pillar electrode 61 is connected to the peripheral surface 63 of the pillar electrode 61. More specifically, opening portions 66 are formed at the peripheral surface 63 at opposite ends of the groove 64 of the pillar electrode 61. When the electronic component 50 is mounted on the circuit board 2, bubbles may be generated in the solder when using a soldering flux, for example. The above configuration, however, can reduce the likelihood of the bubbles staying inside the solder portion 71 between the pillar electrode 61 and the electrode 23 of the circuit board 2. More specifically, in the direction D1, the distance between the electrode 23 of the circuit board 2 and the bottom 65 of the groove 64 of the pillar electrode 61 is greater than the distance between the electrode 23 of the circuit board 2 and the principal surface 62 of the pillar electrode 61. This enables bubbles to enter the groove 64 readily. Moreover, due to the groove 64 being connected to the peripheral surface 63 of the pillar electrode 61, the bubbles move readily in the direction D2, which is the elongated direction of the groove 64, and be released out of the solder portion 71 from the opening portions 66. In other words, when the electronic component 50 is mounted on the circuit board 2, the void generation caused by bubbles does not occur readily in the solder portion 71, which improves the reliability of connection between the pillar electrode 61 and the circuit board 2 in the electronic component 50.

Moreover, in the pillar electrode 61, the bottom 65 of the groove 64 is connected to the peripheral surface 63 at two locations or more (two locations in the case of the pillar electrode 61 illustrated in FIGS. 3A and 3B). More specifically, in the pillar electrode 61, the groove 64 has opposite ends in the direction D2, and the bottom 65 of the groove 64 is connected to the peripheral surface 63 at the opposite ends. As a result, even if bubbles are generated when the electronic component 50 is mounted onto the circuit board 2, the bubbles do not generate the void in the solder portion 71 insofar as the bubbles move to one of the opening portions 66 positioned at the opposite ends of the groove 64. This can further reduce the likelihood of the bubbles generating the void in the solder portion 71 when the electronic component 50 is mounted on the circuit board 2.

### 2 High-Frequency Module

As illustrated in FIG. 5, a high-frequency module 1 is used, for example, in a communication device 100. For example, the communication device 100 is a mobile phone, such as a smartphone. The communication device 100 is not limited to the mobile phone but may be, for example, a wearable terminal, such as a smartwatch. The high-frequency module 1 is able to support, for example, the 4G (4th Generation Mobile Communication) standard and the 5G (5th Generation Mobile Communication) standard. An example of the 4G standard is LTE (which is short for Long Term Evolution, Registered Trade Mark) of 3GPP (which is short for Third Generation Partnership Project, Registered Trade Mark). An example of the 5G standard is 5G NR (New Radio). The high-frequency module 1 can support, for example, Carrier Aggregation and Dual Connectivity.

### (2.1) Circuit Structure of High-Frequency Module

The following describes a circuit structure of the high-frequency module 1 of Embodiment 1 with reference to FIG. 5.

As illustrated in FIG. 5, the high-frequency module 1 of Embodiment 1 includes multiple external-connection terminals 10, the switch 110, matching circuits 121 and 122, the transmission filter 131, the reception filter 132, matching circuits 141 and 142, the power amplifier 151, and the low-noise amplifier 152. Each external-connection terminals 10 include an antenna terminal 11, a signal input terminal 12, and a signal output terminal 13.

The high-frequency module 1 of Embodiment 1 also includes the electronic component 50. The electronic component 50 includes, for example, the transistor Q1. More specifically, the electronic component 50 includes the transistor Q1, for example, as part of the power amplifier 151.

For example, the electronic component 50 of Embodiment 1 includes part of the transmission filter 131 or part of the reception filter 132.

### 2.1.1 Power Amplifier

The power amplifier 151 is an amplifier for amplifying transmitting signals. The power amplifier 151 has an input terminal (not illustrated) and an output terminal (not illustrated). The input terminal of the power amplifier 151 is coupled to a signal processing circuit 17 via the signal input terminal 12. The output terminal of the power amplifier 151 is coupled to the transmission filter 131 via the matching circuit 141.

As illustrated in FIG. 6, the power amplifier 151 includes the transistor Q1. The transistor Q1 has multiple electrodes. For example, the transistor Q1 is a bipolar transistor of which the multiple electrodes include a base BS1, an emitter EM1, and a collector CO1. For example, the base BS1 is coupled to the input terminal of the power amplifier 151. For example, the emitter EM1 is coupled to the ground. For example, the collector CO1 is coupled to the output terminal of the power amplifier 151.

### 2.1.2 Transmission Filter

The transmission filter 131 is a filter that allows transmitting signals to pass. For example, the transmission filter 131 is an acoustic wave filter that includes multiple series-arm resonators and multiple parallel-arm resonators. For example, the acoustic wave filter is a surface acoustic wave (SAW) filter that utilizes surface acoustic waves. The transmission filter 131 has an input terminal (not illustrated) and an output terminal (not illustrated). The input terminal of the transmission filter 131 is coupled to the output terminal of the power amplifier 151 via the matching circuit 141. The output terminal of the transmission filter 131 is coupled to the switch 110 via the matching circuit 121.

### 2.1.3 Low-Noise Amplifier

The low-noise amplifier 152 is an amplifier for amplifying received signals. The low-noise amplifier 152 has an input terminal (not illustrated) and an output terminal (not illustrated). The output terminal of the low-noise amplifier 152 is coupled to the signal processing circuit 17 via the signal output terminal 13. The input terminal of the low-noise amplifier 152 is coupled to the reception filter 132 via the matching circuit 142. For example, the low-noise amplifier 152 includes a transistor serving as a signal-amplifier element.

### 2.1.4 Reception Filter

The reception filter 132 is a filter that allows received signals to pass. For example, the reception filter 132 is an acoustic wave filter that includes multiple series-arm resonators and multiple parallel-arm resonators. For example, the acoustic wave filter is the SAW filter that utilizes surface acoustic waves. The reception filter 132 has an input terminal (not illustrated) and an output terminal (not illustrated). The input terminal of the reception filter 132 is coupled to the switch 110 via the matching circuit 122. The output terminal of the reception filter 132 is coupled to the output terminal of the low-noise amplifier 152 via the matching circuit 142.

### 2.1.5 Switch

The switch 110 selects whether the antenna terminal 11 is coupled to the transmission filter 131 or to the reception filter 132. The switch 110 includes a common terminal 111 and selection terminals 112 and 113 (two selection terminals in the illustrated example). The common terminal 111 is coupled to the antenna terminal 11. The selection terminal 112 is coupled to the transmission filter 131 via the matching circuit 121. The selection terminal 113 is coupled to the reception filter 132 via the matching circuit 122. The switch 110 includes a transistor, for example, serving as a switching element.

### 2.1.6 Matching Circuit

The matching circuit 121 is a circuit for matching impedance between the selection terminal 112 of the switch 110 and the output terminal of the transmission filter 131. The matching circuit 121 includes at least either one capacitor or more or one inductor or more.

The matching circuit 122 is a circuit for matching impedance between the selection terminal 113 of the switch 110 and the input terminal of the reception filter 132. The matching circuit 122 includes at least either one capacitor or more or one inductor or more.

The matching circuit 141 is a circuit for matching impedance between the input terminal of the transmission filter 131 and the output terminal of the power amplifier 151. The matching circuit 141 includes at least either one capacitor or more or one inductor or more.

The matching circuit 142 is a circuit for matching impedance between the output terminal of the reception filter 132 and the input terminal of the low-noise amplifier 152. The matching circuit 142 includes at least either one capacitor or more or one inductor or more.

### 2.2 Structure of High-Frequency Module

The following describes the structure of the high-frequency module 1 of Embodiment 1 with reference to the drawings.

For example, the high-frequency module 1 of Embodiment 1 includes the circuit board 2 and the electronic component 50 as illustrated in FIGS. 1 and 2.

### 2.2.1 Circuit Board

As illustrated in FIG. 2, the circuit board 2 has principal surfaces 21 and 22. The principal surface 21 and the principal surface 22 faces oppositely in the direction D1, which is the thickness direction of the circuit board 2. For example, the circuit board 2 is shaped like a rectangle as viewed in plan in the direction D1.

The electronic component 50 is disposed on the principal surface 21 of the circuit board 2. The circuit board 2 includes multiple electrodes 23 disposed on the principal surface 21. The electrodes 23 are electrically connected to the electronic component 50 disposed on the principal surface 21 of the circuit board 2.

For example, multiple external-connection terminals (not illustrated) are disposed on the principal surface 22 of the circuit board 2.

For example, the circuit board 2 is a multilayer board including multiple dielectric layers and multiple conductive layers. The dielectric layers and the conductive layers are laminated in the direction D1. Each conductive layer is formed so as to have a predetermined conductor pattern depending on a specific layer. Each conductive layer has one or more conductor portions on the surface thereof that extends orthogonally to the direction D1. For example, the material of the conductive layer is copper. The conductive layer includes a ground electrode that can provide ground potential. The circuit board 2 is a low temperature co-fired ceramics (LTCC) board.

### 3 Communication Device

As illustrated in FIG. 5, the communication device 100 includes the high-frequency module 1, the signal processing circuit 17, and an antenna 16.

The antenna 16 is coupled to the antenna terminal 11 of the high-frequency module 1. The antenna 16 has a transmission function, whereby the antenna 16 radiates radio waves containing a transmitting signal output by the high-frequency module 1, and also has a reception function, whereby the antenna 16 receives radio waves containing a received signal from outside and outputs the received signal to the high-frequency module 1.

The signal processing circuit 17 includes an RF signal processing circuit 171 and a baseband signal processing circuit 172. The signal processing circuit 17 processes signals passing through the high-frequency module 1. More specifically, the signal processing circuit 17 processes transmitting signals and received signals.

For example, the RF signal processing circuit 171 is a radio frequency integrated circuit (RFIC). The RF signal processing circuit 171 processes high-frequency signals

The RF signal processing circuit 171 receives a transmitting signal from the baseband signal processing circuit 172 and performs processing, such as up-conversion and amplification. The processed transmitting signal is output to the high-frequency module 1. The RF signal processing circuit 171 also receives a received signal from the high-frequency module 1 and performs processing, such as down-conversion and amplification. The processed received signal is output to the baseband signal processing circuit 172.

For example, the baseband signal processing circuit 172 is a baseband integrated circuit (BBIC). The baseband signal processing circuit 172 receives a transmitting signal from outside of the signal processing circuit 17 and performs predetermined processing. The received signal processed by the baseband signal processing circuit 172 is utilized, for example, as an image signal for displaying an image or as an audio signal for telephone conversation.

The RF signal processing circuit 171 also functions as a control unit that controls the switch 110 included in the high-frequency module 1 in response to transmission/reception of a high-frequency signal (a transmitting signal or a received signal). More specifically, the RF signal processing circuit 171 sends a control signal (not illustrated) to switch the connection of the switch 110 in the high-frequency module 1. Note that the control unit may be provided outside the RF signal processing circuit 171. For example, the control unit may be disposed in the high-frequency module 1 or in the baseband signal processing circuit 172.

### 4 Advantageous Effect

The electronic component 50 of Embodiment 1 includes the substrate 51 and the pillar electrodes 61. The substrate 51 includes the principal surface 511. Each pillar electrode 61 protrudes from the principal surface 511 of the substrate 51 in the thickness direction D1 of the substrate 51. The pillar electrode 61 is positioned between the bump electrode 70 and the principal surface 511 of the substrate 51. The pillar electrode 61 has the principal surface 62 and the peripheral surface 63. The principal surface 62 is in contact with the bump electrode 70. The principal surface 62 is connected to the peripheral surface 63. The pillar electrode 61 includes the groove 64 disposed at the principal surface 62 of the pillar electrode 61. The bottom 65 of the groove 64 is connected to the peripheral surface 63 of the pillar electrode 61. Accordingly, the electronic component 50 of Embodiment 1 can improve the reliability of connection between the pillar electrode 61 and the corresponding electrode 23 of the circuit board 2.

In the electronic component 50 of Embodiment 1, the bottom 65 of the groove 64 is connected to the peripheral surface 63 of the pillar electrode 61 at two locations or more. Accordingly, in the electronic component 50 of Embodiment 1, the void does not occur readily in the solder portion made of the melted bump electrode 70. This enables the electronic component 50 to further improve the reliability of connection between the pillar electrode 61 and the corresponding electrode 23 of the circuit board 2.

In the electronic component 50 of Embodiment 1, the pillar electrode 61 is elongated in the direction D2 that is orthogonal to the thickness direction D1 of the substrate 51. Accordingly, the electronic component 50 of Embodiment 1 can improve heat dissipation from the electronic component 50 to the circuit board 2 on which the electronic component 50 is disposed. Moreover, the electric resistance of the pillar electrode 61 can be reduced, which can reduce the deterioration of the electrical characteristics of the electronic component 50.

The electronic component 50 of Embodiment 1 further includes the transistor Q1 that includes multiple electrodes. More specifically, the pillar electrode 61 is connected to the emitter EM1, which is one of the electrodes of the transistor Q1. Accordingly, in the electronic component 50 of Embodiment 1, the deterioration of the electrical characteristics of the electronic component 50 can be reduced in the case of the emitter of the transistor Q1 being grounded. This leads to an efficient heat dissipation from the transistor Q1, which is a heat-producing component in the electronic component 50.

The high-frequency module 1 of Embodiment 1 includes the electronic component 50 and the circuit board 2. The electronic component 50 is disposed on the circuit board 2. Accordingly, the high-frequency module 1 of Embodiment 1 can improve the reliability of connection of the pillar electrode 61.

Moreover, the communication device 100 of Embodiment 1 includes the high-frequency module 1 and the signal processing circuit 17. The signal processing circuit 17 is connected to the high-frequency module 1. Accordingly, the communication device 100 of Embodiment 1 includes the high-frequency module 1, and the high-frequency module 1 can improve the reliability of connection of the pillar electrode 61 of the high-frequency module 1.

### Embodiment 2

### 1 Structure

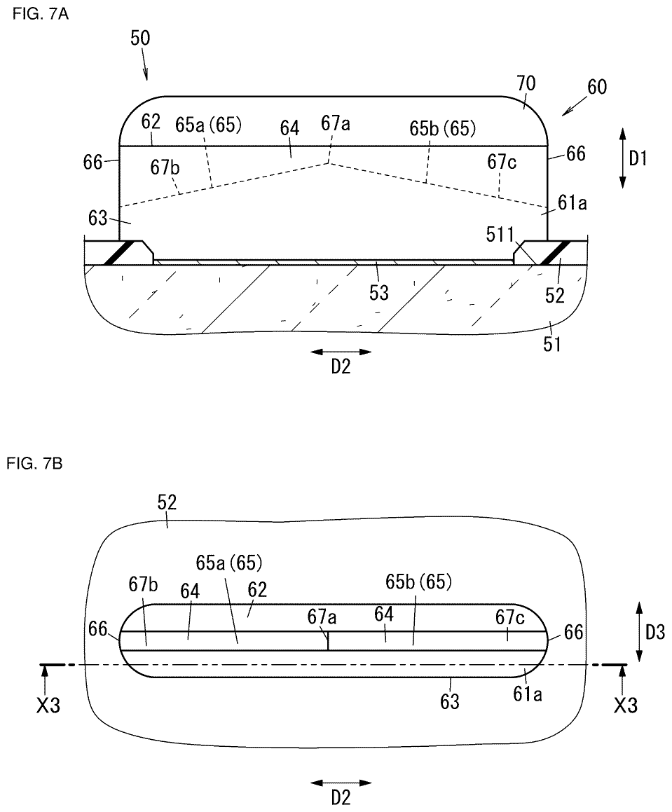

An electronic component 50 according to Embodiment 2 includes a pillar electrode 61a illustrated in FIGS. 7A and 7B in place of the pillar electrode 61. The pillar electrode 61a has a groove 64 that is different in shape from the groove 64 of the pillar electrode 61 included in the electronic component 50 of Embodiment 1. FIG. 7A is a cross-sectional view corresponding to section X3-X3 in FIG. 7B. Note that in FIG. 7A, the hatching for indicating the cross-section is omitted from the illustration of the pillar electrode 61a and the bump electrode 70 as is the case in FIG. 3A. Note that the bump electrode 70 is also omitted in FIG. 7B as is the case in FIG. 3B.

As illustrated in FIG. 7A, the bottom 65 of the groove 64 of the pillar electrode 61a includes a first bottom surface 65a and a second bottom surface 65b. The first bottom surface 65a and the second bottom surface 65b are flat surfaces.

The first bottom surface 65a and the second bottom surface 65b are inclined with respect to the principal surface 62. More specifically, the first bottom surface 65a includes a portion 67a and a portion 67b. For example, the portion 67a is a portion at which the first bottom surface 65a is connected to the second bottom surface 65b. For example, the portion 67b adjoins an opening portion 66 at which the first bottom surface 65a is connected to the peripheral surface 63 of the pillar electrode 61a. The first bottom surface 65a is formed such that the distance between the portion 67b and the principal surface 62 is greater than the distance between the portion 67a and the principal surface 62.

The second bottom surface 65b includes the portion 67a and a portion 67c. For example, the portion 67c adjoins an opening portion 66 at which the second bottom surface 65b is connected to the peripheral surface 63 of the pillar electrode 61a. The second bottom surface 65b is formed such that the distance between the portion 67c and the principal surface 62 is greater than the distance between the portion 67a and the principal surface 62. The portion 67a corresponds to the second portion of the present disclosure, and the portion 67b or the portion 67c corresponds to the first portion of the present disclosure. In the groove 64, the distance between the portion 67b and the opening portion 66 that is a section at which the bottom 65 is connected to the peripheral surface 63 is smaller than the distance between the portion 67a and the opening portion 66. Moreover, in the groove 64, the distance between the portion 67c and the opening portion 66 is smaller than the distance between the portion 67a and the opening portion 66. In other words, the groove 64 is shaped such that the depth becomes greater as the groove 64 comes closer to the peripheral surface 63 and becomes smaller as the groove 64 comes further away from the peripheral surface 63.

Accordingly, in the electronic component 50 of Embodiment 2, when the electronic component 50 is mounted onto the circuit board 2, bubbles produced by the soldering flux or the like can enter the groove 64 easily. The shape of the groove 64 is such that the depth becomes greater as the groove 64 comes closer to the opening portion 66, which enables bubbles to move readily toward the opening portion 66 along the groove 64. In other words, in the electronic component 50 of Embodiment 2, the void generation caused by bubbles does not occur readily in the solder portion 71 when the electronic component 50 is mounted on the circuit board 2.

### 2 Advantageous Effect

In the electronic component 50 of Embodiment 2, the bottom 65 of the groove 64 includes the portion 67a and the portions 67b and 67c. The distance between the portion 67a and the principal surface 62 is smaller than the distance between the portion 67b and the principal surface 62. In addition, the distance between the portion 67a and the principal surface 62 is smaller than the distance between the portion 67c and the principal surface 62. Accordingly, in the electronic component 50 of Embodiment 2, bubbles move readily along the groove 64 when the electronic component 50 is mounted on the circuit board 2. This can improve the reliability of connection between the pillar electrode 61 and the circuit board 2.

According to the electronic component 50 of Embodiment 2, in the groove 64, the distance between the portion 67b and a section 66 at which the bottom 65 of the groove 64 is connected to the peripheral surface 63 of the pillar electrode 61a is smaller than the distance between the portion 67a and the section 66. According to the electronic component 50 of Embodiment 2, in the groove 64, the distance between the portion 67c and the section 66 that is the section at which the bottom 65 of the groove 64 is connected to the peripheral surface 63 of the pillar electrode 61a is also smaller than the distance between the portion 67a and the section 66. Accordingly, in the electronic component 50 of Embodiment 2, bubbles move readily along the groove 64 and is released to the peripheral surface 63 of the pillar electrode 61a when the electronic component 50 is mounted on the circuit board 2. This can further improve the reliability of connection between the pillar electrode 61 and the circuit board 2.

### Embodiment 3

### 1 Structure

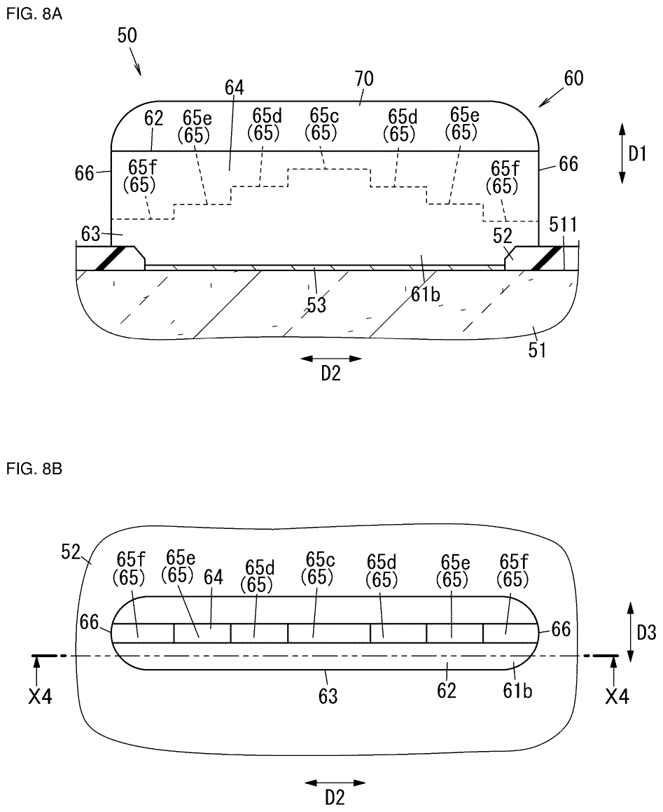

An electronic component 50 according to Embodiment 3 includes a pillar electrode 61b illustrated in FIGS. 8A and 8B in place of the pillar electrode 61. The pillar electrode 61b has a groove 64 that is different in shape from the groove 64 of the pillar electrode 61 included in the electronic component 50 of Embodiment 1. FIG. 8A is a cross-sectional view corresponding to section X4-X4 in FIG. 8B. Note that in FIG. 8A, the hatching for indicating the cross-section is omitted from the illustration of the pillar electrode 61b and the bump electrode 70 as is the case in FIG. 3A. Note that the bump electrode 70 is also omitted in FIG. 8B as is the case in FIG. 3B.

In the pillar electrode 61b, the bottom 65 of the groove 64 is shaped like stairs as illustrated in FIG. 8A. More specifically, the bottom 65 of the groove 64 includes one bottom surface 65c, two bottom surfaces 65d, two bottom surfaces 65e, and two bottom surfaces 65f. For example, the bottom surfaces 65c to 65f are flat surfaces.

The bottom surfaces 65c to 65f are arranged in the direction D2 in the following order: the bottom surface 65f, the bottom surface 65e, the bottom surface 65d, the bottom surface 65c, the bottom surface 65d, the bottom surface 65e, and the bottom surface 65f. The two bottom surfaces 65f are positioned at the same distance from the principal surface 62. The two bottom surfaces 65e are positioned at the same distance from the principal surface 62. The two bottom surfaces 65d are positioned at the same distance from the principal surface 62. In the order of the bottom surface 65c, the bottom surface 65d, the bottom surface 65e, and the bottom surface 65f, the distance from the principal surface 62 becomes greater. More specifically, the distance between the bottom surface 65d and the principal surface 62 is greater than the distance between the bottom surface 65c and the principal surface 62. The distance between the bottom surface 65e and the principal surface 62 is greater than the distance between the bottom surface 65d and the principal surface 62. The distance between the bottom surface 65f and the principal surface 62 is greater than the distance between the bottom surface 65e and the principal surface 62. The bottom surface 65f corresponds to the first portion of the present disclosure and also corresponds to the first bottom surface of the present disclosure. The bottom surface 65e corresponds to the second portion of the present disclosure and also corresponds to the second bottom surface of the present disclosure. The bottom surface 65d corresponds to the third bottom surface of the present disclosure.

In the electronic component 50 of Embodiment 3, bubbles produced by the soldering flux or the like can enter the groove 64 easily when the electronic component 50 is mounted onto the circuit board 2. The groove 64 is shaped such that the depth becomes greater as the groove 64 comes closer to the opening portion 66, which enables bubbles to move readily toward the opening portion 66 along the groove 64. In other words, in the electronic component 50, the void generation caused by bubbles does not occur readily in the solder portion 71, which improves the reliability of connection between the pillar electrode 61b and the circuit board 2.

In the electronic component 50 of Embodiment 3, the bottom 65 of the groove 64 is shaped like stairs. Accordingly, the groove 64 can be formed easily, for example, by etching the pillar electrode 61b repeatedly using different photomasks.

### 2 Advantageous Effect

In the electronic component 50 of Embodiment 3, the bottom 65 of the groove 64 includes the bottom surface 65f and the bottom surface 65e. The bottom surface 65f is a flat surface that includes a portion 65f, and the bottom surface 65e is a flat surface that includes a portion 65e. Accordingly, in the electronic component 50 of Embodiment 3, bubbles move readily along the groove 64 and is released to the peripheral surface 63 of the pillar electrode 61b when the electronic component 50 is mounted on the circuit board 2. This can further improve the contact between the pillar electrode 61 and the circuit board 2.

In the electronic component 50 of Embodiment 3, the bottom 65 of the groove 64 includes the bottom surface 65d of which the distance from the principal surface 62 of the pillar electrode 61b is smaller than the distance between the portion 65e and the principal surface 62 of the pillar electrode 61b. Accordingly, in the electronic component 50 of Embodiment 3, bubbles move readily along the groove 64 and is released to the peripheral surface 63 of the pillar electrode 61b when the electronic component 50 is mounted on the circuit board 2. This can further improve the contact between the pillar electrode 61 and the circuit board 2.

### Embodiment 4

### 1 Structure

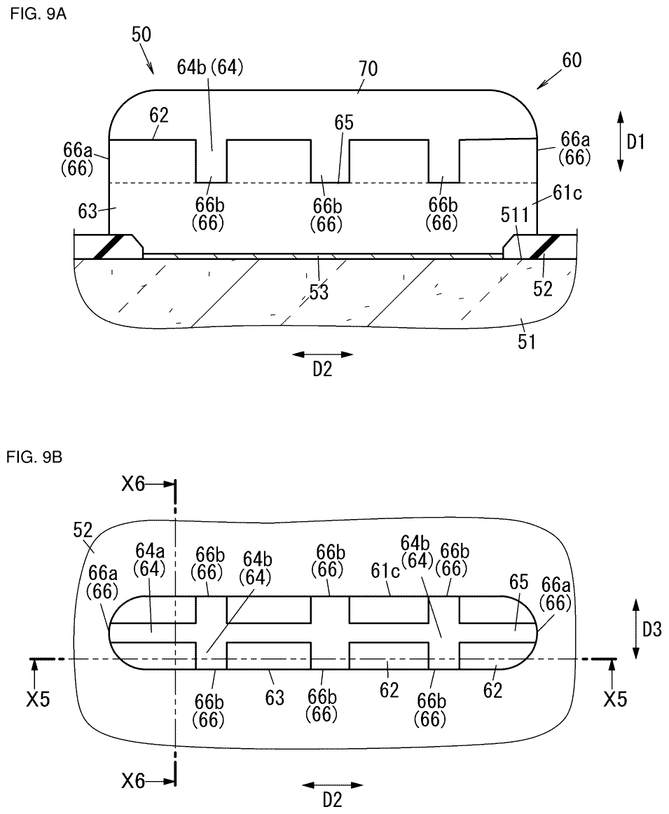

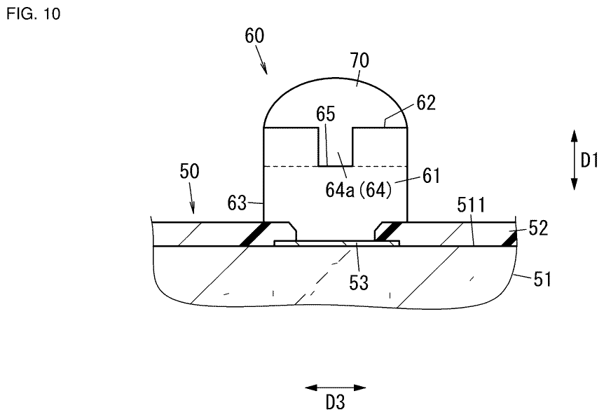

An electronic component 50 according to Embodiment 4 includes a pillar electrode 61c illustrated in FIGS. 9A, 9B, and 10 in place of the pillar electrode 61. The pillar electrode 61c has a groove 64 that is different in shape from the groove 64 of the pillar electrode 61 included in the electronic component 50 of Embodiment 1. FIG. 9A is a cross-sectional view corresponding to section X5-X5 in FIG. 9B. FIG. 10 is a cross-sectional view corresponding to section X6-X6 in FIG. 9B. Note that in FIGS. 9A and 10, the hatching for indicating the cross-section is omitted from the illustration of the pillar electrode 61a and the bump electrode 70 as is the case in FIGS. 3A and 4. Note that the bump electrode 70 is also omitted in FIG. 9B as is the case in FIG. 3B.

As illustrated in FIGS. 9A and 9B, the groove 64 of the pillar electrode 61c includes a first groove 64a and multiple second grooves 64b (three second grooves 64b in the example illustrated in FIGS. 9A and 9B). Note that the bump electrode 70 is omitted in FIG. 9B as is the case in FIG. 3B.

The first groove 64a is elongated in the direction D2, which is the longitudinal direction of the pillar electrode 61c. The bottom 65 of the first groove 64a is connected to the peripheral surface 63 at the opposite ends of the first groove 64a in the direction D2. In other words, the pillar electrode 61c has opening portions 66a at opposite ends thereof in the direction D2 where the first groove 64a opens at the peripheral surface 63.

In addition, the second grooves 64b are formed so as to extend in a direction intersecting the direction D2 as illustrated in FIGS. 9A, 9B, and 10. More specifically, the second grooves 64b are elongated in the direction D3 that orthogonally intersects both of the directions D1 and D2. Each second groove 64b has opposite ends in the direction D3, and the bottom 65 of the second groove 64b is connected to the peripheral surface 63 at the opposite ends. In other words, the pillar electrode 61c has multiple opening portions 66b at the opposite ends of the pillar electrode 61c in the direction D3, and respective second grooves 64b open at the peripheral surface 63 at the opening portions 66b.

Accordingly, in the electronic component 50 of Embodiment 4, the bottom 65 of the groove 64 in the pillar electrode 61c is connected to the peripheral surface 63 at multiple locations. Moreover, in the electronic component 50 of Embodiment 4, the groove 64 includes the first groove 64a and the second grooves 64b that intersect the first groove 64a. Accordingly, in the electronic component 50 of Embodiment 4, bubbles do not stay readily in the solder portion that is made of the melted bump electrode 70 when the electronic component 50 is mounted on the circuit board 2. In other words, when the electronic component 50 is mounted on the circuit board 2, the void generation caused by bubbles does not occur readily in the solder portion 71, which improves the reliability of connection between the pillar electrode 61 and the circuit board 2 in the electronic component 50.

### 2 Advantageous Effect

In the electronic component 50 of Embodiment 4, the groove 64 includes the first groove 64a and the second grooves 64b. The first groove 64a is elongated in the direction D2, which is the longitudinal direction of the pillar electrode 61c. The second grooves 64b intersect the first groove 64a. The bottom 65 of the first groove 64a and the bottoms 65 of the second grooves 64b are connected to the peripheral surface 63 of the pillar electrode 61c. Accordingly, in the electronic component 50 of Embodiment 4, when the electronic component 50 is mounted on the circuit board 2, the void generation caused by bubbles does not occur readily in the solder portion 71, which improves the reliability of connection between the pillar electrode 61 and the circuit board 2.

### Embodiment 5

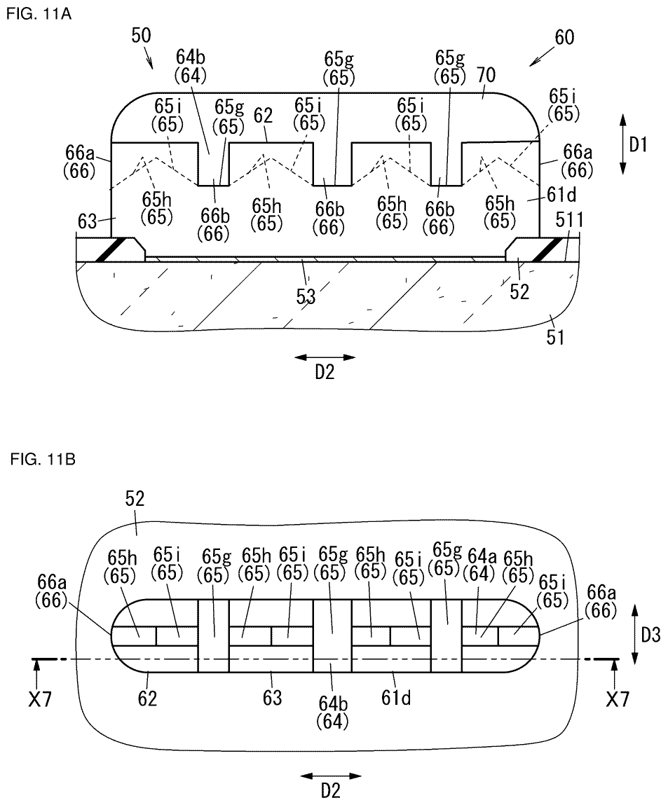

An electronic component 50 according to Embodiment 5 includes a pillar electrode 61d illustrated in FIGS. 11A and 11B in place of the pillar electrode 61. The pillar electrode 61d has a groove 64 that is different in shape from the groove 64 of the pillar electrode 61 included in the electronic component 50 of Embodiment 1. FIG. 11A is a cross-sectional view corresponding to section X7-X7 in FIG. 11B. Note that in FIG. 11A, the hatching for indicating the cross-section is omitted from the illustration of the pillar electrode 61d and the bump electrode 70 as is the case in FIG. 3A. Note that the bump electrode 70 is also omitted in FIG. 11B as is the case in FIG. 3B.

As is the case for the pillar electrode 61c of the electronic component of Embodiment 4, the groove 64 of the pillar electrode 61d includes the first groove 64a and multiple second grooves 64b (three second grooves 64a in the example illustrated in FIGS. 11A and 11B).

The first groove 64a is elongated in the direction D2, which is the longitudinal direction of the pillar electrode 61d. The bottom 65 of the first groove 64a is connected to the peripheral surface 63 at the opposite ends of the first groove 64a in the direction D2. In other words, the pillar electrode 61d has opening portions 66a at opposite ends thereof in the direction D2 where the first groove 64a opens at the peripheral surface 63.

In the first groove 64a of the pillar electrode 61d, the depth becomes greater as the first groove 64a comes closer to the opening portion 66 and becomes smaller as the first groove 64a comes further away from the opening portion 66, as is the case for the groove 64 of the pillar electrode 61a. More specifically, the bottom of the first groove 64a includes multiple bottom surfaces 65g, multiple bottom surfaces 65h, and multiple bottom surfaces 65i. For example, each bottom surface 65g is positioned at a constant distance from the principal surface 62 and is connected to the bottom of a corresponding second groove 64b. For example, each bottom surface 65h is a flat surface that is inclined such that the distance between the principal surface 62 and a portion of the bottom surface 65h being in contact with an adjacent bottom surface 65g or in contact with the opening portion 66a is greater than the distance between the principal surface 62 and a portion of the bottom surface 65h being in contact with an adjacent bottom surface 65i. For example, each bottom surface 65i is a flat surface that is inclined such that the distance between the principal surface 62 and a portion of the bottom surface 65i being in contact with an adjacent bottom surface 65g or in contact with the opening portion 66a is greater than the distance between the principal surface 62 and a portion of the bottom surface 65i being in contact with an adjacent bottom surface 65h. Put another way, in the first groove 64a, the depth becomes greater as the first groove 64a comes closer to the opening portion 66a or to an intersection between the first groove 64a and a second groove 64b and the depth becomes smaller as the first groove 64a comes further away from the opening portion 66a or from the intersection.

Accordingly, in the electronic component 50 of Embodiment 5, bubbles do not stay readily in the solder portion that is made of the melted bump electrode 70 when the electronic component 50 is mounted on the circuit board 2. For example, if a bubble is generated inside or near a second groove 64b, the bubble moves readily along the second groove 64b toward the opening portion 66b since the depth of the second groove 64b is equal to or greater than the depth of the first groove 64a. If a bubble is generated inside or near the first groove 64a, the bubble moves readily along the first groove 64a to the opening portion 66a or to a second groove 64b since the first groove 64a has a greater depth near the second groove 64b and near the opening portion 66a. As described above, the bubble inside the second groove 64b moves readily along the second groove 64b to the opening portion 66b. Accordingly, a bubble generated at any location does not tend to stay in the solder portion.

Accordingly, the electronic component 50 of Embodiment 5 can provide advantageous effects of both of the electronic components 50 of Embodiment 2 and Embodiment 4.

### Embodiment 6

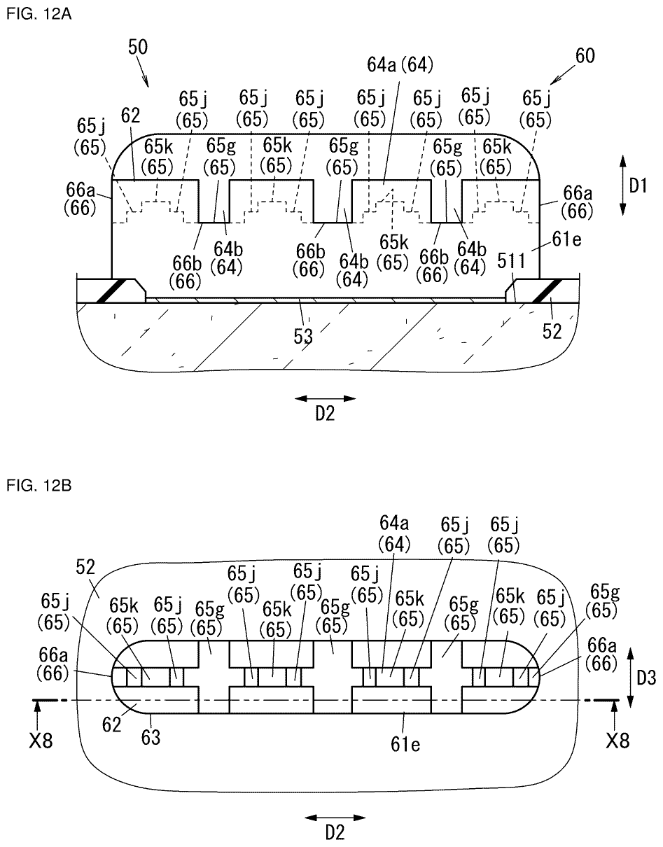

An electronic component 50 according to Embodiment 6 includes a pillar electrode 61e illustrated in FIGS. 12A and 12B in place of the pillar electrode 61. The pillar electrode 61e has a groove 64 that is different in shape from the groove 64 of the pillar electrode 61 included in the electronic component 50 of Embodiment 1. FIG. 12A is a cross-sectional view corresponding to section X8-X8 in FIG. 12B. Note that in FIG. 12A, the hatching for indicating the cross-section is omitted from the illustration of the pillar electrode 61e and the bump electrode 70 as is the case in FIG. 3A. Note that the bump electrode 70 is also omitted in FIG. 12B as is the case in FIG. 3B.

As is the case for the pillar electrode 61c of the electronic component 50 of Embodiment 4, the groove 64 of the pillar electrode 61e includes the first groove 64a and multiple second grooves 64b (three second grooves 64b in the example illustrated in FIGS. 12A and 12B).

The first groove 64a is elongated in the direction D2, which is the longitudinal direction of the pillar electrode 61e. The bottom 65 of the first groove 64a is connected to the peripheral surface 63 at the opposite ends of the first groove 64a in the direction D2. In other words, the pillar electrode 61e has opening portions 66a at opposite ends thereof in the direction D2 where the first groove 64a opens at the peripheral surface 63.

In the first groove 64a of the pillar electrode 61e, the depth becomes greater as the first groove 64a comes closer to the opening portion 66 and becomes smaller as the first groove 64a comes further away from the opening portion 66, as is the case for the groove 64 of the pillar electrode 61a. More specifically, the bottom 65 of the first groove 64a includes multiple bottom surfaces 65g, multiple bottom surfaces 65j, and multiple bottom surfaces 65k. In the pillar electrode 61e, a bottom surface 65j, a bottom surface 65k, and a bottom surface 65j are arranged in this order between two bottom surfaces 65g in the direction D2. For example, each bottom surface 65g is a flat surface positioned at a constant distance from the principal surface 62 and is continuous to the bottom 65 of a corresponding second groove 64b. For example, each bottom surface 65j is a flat surface, and the distance between the bottom surface 65j and the principal surface 62 is smaller than the distance between the bottom surface 65g and the principal surface 62. For example, each bottom surface 65k is a flat surface, and the distance between the bottom surface 65k and the principal surface 62 is smaller than the distance between the bottom surface 65j and the principal surface 62. Put another way, in the first groove 64a, the depth becomes greater as the first groove 64a comes closer to the opening portion 66a or to an intersection between the first groove 64a and a second groove 64b and the depth becomes smaller as the first groove 64a comes further away from the opening portion 66a or from the intersection.

Accordingly, in the electronic component 50 of Embodiment 6, bubbles do not stay readily in the solder portion that is made of the melted bump electrode 70 when the electronic component 50 is mounted on the circuit board 2. For example, if a bubble is generated inside or near a second groove 64b, the bubble moves readily along the second groove 64b toward the opening portion 66b since the depth of the second groove 64b is equal to or greater than the depth of the first groove 64a. If a bubble is generated inside or near the first groove 64a, the bubble moves readily along the first groove 64a to the opening portion 66a or to a second groove 64b since the first groove 64a has a greater depth near the second groove 64b and near the opening portion 66a. As described above, the bubble inside the second groove 64b moves readily along the second groove 64b to the opening portion 66b. Accordingly, a bubble generated at any location does not tend to stay in the solder portion.

Accordingly, the electronic component 50 of Embodiment 6 can provide the advantageous effects of both of the electronic components 50 of Embodiment 3 and Embodiment 4.

### Variations

The following describes variations of the embodiments.

In the electronic components 50 according to Embodiments 1 to 6, for example, multiple grooves may be formed in each of the pillar electrodes 61 to 61e so as to extend in the longitudinal direction thereof. In each of the pillar electrodes 61 to 61e, multiple grooves may be formed so as to extend in a direction intersecting the longitudinal direction thereof.

In the electronic components 50 according to Embodiments 1 to 6, each of the pillar electrodes 61 to 61e may have any arbitrary shape, such as a circle or a rectangle, as viewed in plan in the direction D1. Moreover, as viewed in plan in the direction D1, each of the pillar electrodes 61 to 61e do not need to have the elongated shape.

In the electronic components 50 of Embodiments 2 and 5, the bottom 65 of the groove 64 of each of the pillar electrodes 61a and 61d may have a curved surface.

In the electronic components 50 of Embodiment 3, the bottom 65 of the groove 64 of the pillar electrode 61b does not need to be symmetrical in the direction D2. Similarly, in the electronic components 50 of Embodiment 6, the bottom 65 of the first groove 64a of the pillar electrode 61e does not need to be symmetrical in the direction D2. For example, a portion of the bottom 65 of the groove 64 may be shaped like stairs.

In the electronic components 50 of Embodiments 1 to 6, each of the pillar electrodes 61 to 61e may be coupled, for example, to the base or to the collector of the transistor Q1. The transistor Q1 may be a field-effect transistor, and each of the pillar electrodes 61 to 61e may be coupled to any one of the gate, the source, and the drain of the transistor Q1. In the electronic component 50, the low-noise amplifier 152 or in the switch 110 may include a transistor.

### Aspects

According to a first aspect, an electronic component (50) includes a substrate (51) and a pillar electrodes (61 to 61e). The substrate (51) includes a first principal surface (511). The pillar electrode (61 to 61e) protrudes from the first principal surface (511) of the substrate (51) in a thickness direction (D1) of the substrate (51). The pillar electrode (61 to 61e) is positioned between the first principal surface (511) of the substrate (51) and a bump electrode (70). The pillar electrode (61 to 61e) includes a second principal surface (62) and a peripheral surface (63). The second principal surface (62) is in contact with the bump electrode (70). The peripheral surface (63) is connected to the second principal surface (62). The pillar electrode (61 to 61e) includes a groove (64) disposed at the second principal surface (62) of the pillar electrode (61 to 61e). A bottom (65) of the groove (64) is connected to the peripheral surface (63) of the pillar electrode (61 to 61e).

According to the electronic component 50 of the above aspect, the reliability of connection of the pillar electrode (61 to 61e) can be improved.

According to a second aspect, in the electronic component (50) of the first aspect, the bottom (65) of the groove (64) is connected to the peripheral surface (63) of the pillar electrode (61 to 61e) at two locations or more.

According to the electronic component (50) of the above aspect, a void does not occur readily in the bump electrode (70), which can further improve the reliability of connection of the pillar electrode (61 to 61e).

According to a third aspect, in the electronic component 50 of the first or second aspect, the pillar electrode (61 to 61e) is elongated in a direction (D2) that is orthogonal to the thickness direction (D1) of the substrate (51).

According to the electronic component (50) of the above aspect, heat dissipation can be improved from the electronic component (50) to a circuit board (2) on which the electronic component (50) is disposed. Moreover, according to the electronic component (50) of the above aspect, the electric resistance of the pillar electrode (61 to 61e) can be reduced, which can reduce the deterioration of the electrical characteristics of the electronic component (50).

According to a fourth aspect, the electronic component 50 of the third aspect further includes a transistor (Q1). The transistor (Q1) includes multiple electrodes. The pillar electrode (61 to 61e) is connected to one (EM1) of the multiple electrodes of the transistor (Q1).

According to the electronic component (50) of the above aspect, the deterioration of the electrical characteristics of the electronic component (50) can be reduced. According to the electronic component (50) of the above aspect, heat dissipation from the transistor (Q1) included in the electronic component (50) is improved.

According to a fifth aspect, in the electronic component 50 of any one of the first to fourth aspects, the groove (64) includes a first groove (64a) and a second groove (64b). The first groove (64a) is elongated in a longitudinal direction (D2) of the pillar electrode (61c, 61e). The second groove (64b) intersects the first groove (64a). The bottom (65) of the first groove (64a) and the bottom (65) of the second groove (64b) are connected to the peripheral surface (63) of the pillar electrode (61c, 61e).

According to a sixth aspect, in the electronic component 50 of any one of the first to fifth aspects, the bottom (65) of the groove (64) includes a first portion (67b, 67c, 65f) and a second portion (67b, 65e). A distance between the first portion (67a, 67c, 65f) and the second principal surface (62) of the pillar electrode (61a, 61b, 61d, 61e) is greater than a distance between the second portion (67a, 65e) and the second principal surface (62) of the pillar electrode (61a, 61b, 61d, 61e).

According to the electronic component (50) of the above aspect, bubbles move readily along the groove (64) when the electronic component (50) is mounted on the circuit board (2), which improves the contact between the pillar electrode (61a, 61b, 61d, 61e) and the circuit board (2).

According to a seventh aspect, in the electronic component 50 of the sixth aspect, the bottom (65) of the groove (64) includes a first bottom surface (65f) and a second bottom surface (65e). The first bottom surface (65f) is a flat surface including the first portion (65f). The second bottom surface (65e) is a flat surface including the second portion (65e).

According to the electronic component (50) of the above aspect, bubbles move readily along the groove (64) when the electronic component (50) is mounted on the circuit board (2), which improves the contact between the pillar electrode (61a, 61b, 61d, 61e) and the circuit board (2).

According to an eighth aspect, in the electronic component 50 of the seventh aspect, the bottom (65) of the groove (64) includes a third bottom surface (65d) of which a distance from the second principal surface (62) of the pillar electrode (61b) is smaller than the distance between the second portion (65e) and the second principal surface (62) of the pillar electrode (61b).

According to the electronic component (50) of the above aspect, bubbles move more readily along the groove (64) when the electronic component (50) is mounted on the circuit board (2). This can improve the contact between the pillar electrode (61a, 61b, 61d, 61e) and the circuit board (2).

According to a ninth aspect, in the electronic component 50 of any one of the sixth to eighth aspects, in the groove (64), a distance between the first portion (67b, 67c) and a section (66) at which the bottom (65) of the groove (64) is connected to the peripheral surface (63) of the pillar electrode (61a, 61b, 61d, 61e) is smaller than a distance between the second portion (67a) and the section (66).

According to the electronic component (50) of the above aspect, bubbles move readily along the groove (64) and are released at the peripheral surface (63) of the pillar electrode (61a, 61b, 61d, 61e) when the electronic component (50) is mounted on the circuit board (2). This improves the contact between the pillar electrode (61a, 61b, 61d, 61e) and the circuit board (2).

According to a tenth aspect, a high-frequency module (1) includes the electronic component (50) of any one of the first to ninth aspects and the circuit board (2). The electronic component (50) is disposed on the circuit board (2).

The high-frequency module (1) of the above aspect can improve the reliability of connection of the pillar electrode (61).

According to an eleventh aspect, a communication device (100) includes the high-frequency module (1) of the tenth aspect and a signal processing circuit (17). The signal processing circuit (17) is connected to the high-frequency module (1).

According to the communication device (100) of the above aspect, the reliability of connection of the pillar electrode 61 can be improved in the high-frequency module (1).

What is claimed is:

1. An electronic component comprising:
a substrate including a first principal surface; and
a pillar electrode protruding from the first principal surface of the substrate in a thickness direction of the substrate and being between the first principal surface and a bump electrode, wherein
the pillar electrode includes
a second principal surface in contact with the bump electrode, and
a peripheral surface connected to the second principal surface,
the pillar electrode includes a groove at the second principal surface of the pillar electrode, and
a bottom of the groove is connected to the peripheral surface of the pillar electrode.

2. The electronic component according to claim 1, wherein
the bottom of the groove is connected to the peripheral surface of the pillar electrode at two locations or more.

3. The electronic component according to claim 1, wherein
the pillar electrode is elongated in a direction orthogonal to the thickness direction of the substrate.

4. The electronic component according to claim 3, further comprising:
a transistor including multiple electrodes, wherein
the pillar electrode is coupled to one of the multiple electrodes of the transistor.

5. The electronic component according to claim 3, wherein
the groove includes
a first groove extending in a longitudinal direction of the pillar electrode, and
a second groove intersecting the first groove, and
a bottom of the first groove and a bottom of a second groove are connected to the peripheral surface of the pillar electrode.

6. The electronic component according to claim 1, wherein
the bottom of the groove includes a first portion and a second portion, and
a distance between the first portion and the second principal surface of the pillar electrode is greater than a distance between the second portion and the second principal surface of the pillar electrode.

7. The electronic component according to claim 6, wherein
the bottom of the groove includes
a first bottom surface that is a flat surface including the first portion, and
a second bottom surface that is a flat surface including the second portion.

8. The electronic component according to claim 7, wherein
the bottom of the groove further includes a third bottom surface of which a distance from the second principal surface of the pillar electrode is smaller than the distance between the second portion and the second principal surface of the pillar electrode.

9. The electronic component according to claim 6, wherein
in the groove, a distance between the first portion and a section at which the bottom of the groove is connected to the peripheral surface of the pillar electrode is smaller than a distance between the second portion and the section.

10. A high-frequency module comprising:
the electronic component according to claim 1; and
a circuit board on which the electronic component is disposed.

11. A communication device comprising:
the high-frequency module according to claim 10; and
a signal processing circuit connected to the high-frequency module.

12. The electronic component according to claim 2, wherein
the pillar electrode is elongated in a direction orthogonal to the thickness direction of the substrate.

13. The electronic component according to claim 12, further comprising:
a transistor including multiple electrodes, wherein
the pillar electrode is coupled to one of the multiple electrodes of the transistor.

14. The electronic component according to claim 12, wherein
the groove includes
a first groove extending in a longitudinal direction of the pillar electrode, and
a second groove intersecting the first groove, and
a bottom of the first groove and a bottom of a second groove are connected to the peripheral surface of the pillar electrode.

15. The electronic component according to claim 2, wherein
the bottom of the groove includes a first portion and a second portion, and
a distance between the first portion and the second principal surface of the pillar electrode is greater than a distance between the second portion and the second principal surface of the pillar electrode.

16. The electronic component according to claim 15, wherein
the bottom of the groove includes
a first bottom surface that is a flat surface including the first portion, and
a second bottom surface that is a flat surface including the second portion.

17. The electronic component according to claim 16, wherein
the bottom of the groove further includes a third bottom surface of which a distance from the second principal surface of the pillar electrode is smaller than the distance between the second portion and the second principal surface of the pillar electrode.

18. The electronic component according to claim 15, wherein
in the groove, a distance between the first portion and a section at which the bottom of the groove is connected to the peripheral surface of the pillar electrode is smaller than a distance between the second portion and the section.

19. A high-frequency module comprising:
the electronic component according to claim 2; and
a circuit board on which the electronic component is disposed.

20. A communication device comprising:
the high-frequency module according to claim 19; and
a signal processing circuit connected to the high-frequency module.
